(19) United States
(12) Patent Application Publication
(10) Pub. No.: US 2024/0275124 A1
(43) Pub. Date: Aug. 15, 2024

(54) LASER DEVICE

(71) Applicant: TRUMPF Photonic Components GmbH, Ulm (DE)

(72) Inventors: Holger Joachim Moench, BM Vaals (NL); Stephan Gronenborn, Aachen (DE)

(21) Appl. No.: 18/645,437

(22) Filed: Apr. 25, 2024

Related U.S. Application Data
(63) Continuation of application No. PCT/EP2022/079855, filed on Oct. 26, 2022.

(30) Foreign Application Priority Data
Oct. 29, 2021 (DE) 10 2021 128 379.5

(51) Int. Cl. H01S 5/02253; H01S 5/42

(52) U.S. Cl. CPC H01S 5/02253; H01S 5/423

(57) ABSTRACT

A laser device includes a semiconductor laser arrangement comprising a plurality of semiconductor lasers, and an ocular arrangement comprising a plurality of ocular units. Each ocular unit includes a stop portion of a respective semiconductor laser and an optical element. Each respective semiconductor laser corresponds to a respective ocular unit such that laser light emitted by the respective semiconductor laser and delimited by the stop portion propagates through the optical element of the respective ocular unit. A relative position of the stop portion with respect to the optical element of a first ocular unit differs from a relative position of the stop portion with respect to the optical element of at least a second ocular unit, and/or a stop portion geometry of the stop portion of the first ocular unit differs from the stop portion geometry of the stop portion of the second ocular unit.

### CROSS REFERENCE TO RELATED APPLICATIONS

This application is a continuation of International Application No. PCT/EP2022/079855 (WO 2023/072979 A1), filed on Oct. 26, 2022, and claims benefit to German Patent Application No. DE 10 2021 128 379.5, filed on Oct. 29, 2021. The aforementioned applications are hereby incorporated by reference herein.

### FIELD

Embodiments of the present invention relate to a laser device having a semiconductor laser arrangement comprising a plurality of semiconductor lasers.

### BACKGROUND

In the smartphone sector, VCSEL arrays are used in combination with separate optical diffusers for the purpose of illuminating a scene to be recorded by a camera. The optical diffusers scatter the laser light emitted by the VCSEL array, with the result that an area can be illuminated. As a result, the light intensity in the central zone of the illuminated area is sufficiently high for a majority of the camera applications, especially of a smartphone. However, the light intensity in the region of the edges of the illuminated area reduces continuously and widely in relation to the central zone. According to this, the light intensity in the edge region of the illuminated area is below the light intensity required for a majority of the camera applications.

### SUMMARY

Embodiments of the present invention provide a laser device that includes a semiconductor laser arrangement comprising a plurality of semiconductor lasers, and an ocular arrangement comprising a plurality of ocular units. Each ocular unit includes a stop portion of a respective semiconductor laser and an optical element. Each respective semiconductor laser corresponds to a respective ocular unit such that laser light emitted by the respective semiconductor laser and delimited by the stop portion propagates through the optical element of the respective ocular unit. A relative position of the stop portion with respect to the optical element of a first ocular unit differs from a relative position of the stop portion with respect to the optical element of at least a second ocular unit, and/or a stop portion geometry of the stop portion of the first ocular unit differs from the stop portion geometry of the stop portion of the second ocular unit.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a laser device known from the prior art, having a diffuser and a semiconductor laser arrangement;

FIG. 2 shows a laser device having an ocular arrangement disposed upstream of the semiconductor laser arrangement according to some embodiments;

FIG. 3 shows an intensity diagram of an emitted laser light which illuminates an area, according to some embodiments;

FIG. 4 shows a laser device in which a stop portion is positioned off-center in relation to an optical element of at least one ocular unit, according to some embodiments; and

FIG. 5 shows a laser device in which stop portions of adjacent ocular unit are shaped differently, according to some embodiments.

### DETAILED DESCRIPTION

Embodiments of the invention provide a laser device for creating an overall radiation resulting from a plurality of individual radiations, the light intensity of which along a plane aligned across the propagation direction of the laser light is more homogeneous vis-à-vis a laser device having a diffuser.

According to embodiments of the present invention, a laser device includes a semiconductor laser arrangement, which comprises a plurality of semiconductor lasers, and an ocular arrangement, which comprises a plurality of ocular units, with the ocular units each comprising a stop portion of a semiconductor laser and an optical element, with each individual one of the semiconductor lasers being assigned a single ocular unit such that the laser light emitted by the respective semiconductor laser and delimited by the stop portion propagates through the optical element of the respectively assigned ocular unit, with a relative position of the stop portion with respect to the optical element of a first ocular unit differing from the relative position of the stop portion with respect to the optical element of at least one second ocular unit and/or a stop portion geometry of the stop portion of the first ocular unit differing from the stop portion geometry of the stop portion of at least one second ocular unit. The laser light diverges and illuminates the area in the far field. The laser light emerges from the ocular unit as a laser light cone. By preference, each semiconductor laser emits laser light for an individual laser light cone. At least a first and a second laser light cone are superimposed, especially in the far field.

Purely by way of example, it is possible that the same number of first and second ocular units are installed in the laser device, the laser light emitted by said ocular units superimposing in the far field independently of the configuration of the first and second ocular units in the ocular arrangement.

In principle, the relative positions can be related to an arrangement direction of the ocular units, the optical elements and/or the stop portions. It is also conceivable that the relative position emerges from displacements of the ocular units, the optical elements and/or the stop portions along a first and a second arrangement direction.

The ocular unit can be understood to be a unit made up of stop portion and optical element. The ocular unit preferably has the function of an ocular constructed from a stop and a lens, even though the ocular unit does not represent a separate device. It is preferably integrated in the laser device in one piece.

The stop portion can have a stop function and delimit the laser light in respect of the solid angle with which the laser light illuminates the area to be illuminated. In particular, the stop portion has the function of an aperture.

By preference, the optical element can be designed as a refractive lens or as a lens containing photonic metamaterial. The optical element images the stop portion and delimits the illuminated area at the edge with a sharpness beyond the capability of a laser device equipped with a diffuser. In comparison with a laser device having a diffuser, a larger proportion of the illuminated area has a largely homogenous light intensity as a result.

This effect is amplified if the laser light emitted by a plurality of semiconductor lasers is superimposed, whereby the light intensity is increased in the homogenously illuminated portion of the illuminated area. To this end, the images of the stop portions are preferably projected exactly on one another such that the edge regions of the illuminated area are delimited more sharply from a non-illuminated region than is the case for a laser device equipped with a diffuser.

The central zone can be distinguished in that it is surrounded by a light intensity that reduces continuously radially outwardly to a global intensity minimum.

Advantageously, the stop portion can have a stop axis of symmetry and the optical element can have an optical axis, with the stop axis of symmetry and the optical axis of an ocular unit being overlaid on one another or positioned approximately parallel relative to one another at an axial spacing. The axial spacing is the distance between two axes. The two axes approximately parallel to one another have an axial spacing aligned in the transverse direction.

In an advantageous development, provision can be made for the optical axes of optical elements from different ocular units to be aligned approximately parallel to one another, with axial spacings of at least one first optical axis with respect to two directly adjacent second optical axes having different magnitudes and/or different alignments. At least one axial spacing differs from all further axial spacings of the laser device. It is conceivable that at least some of the axial spacings have the same magnitude. In particular, first axial spacings and second axial spacings between respective first and second optical axes have different magnitudes and/or different alignments along at least one arrangement direction, with there preferably being the same number of first and second axial spacings. In a further alternative, all axial spacings have different magnitudes.

It can be preferable for the optical elements to be arranged in an array arrangement which is preferably formed as a one-piece lens arrangement, with the axial spacings between the first optical axis and the directly adjacent second optical axes repeating periodically along the array arrangement. The one-piece lens arrangement can be shaped in a wafer or any other portion of the body underlying the semiconductor lasers, for example. Further, the axial spacings repeat regularly along an imaginary arrangement plane, in which the optical elements are arranged in array-like fashion.

In order to obtain a good superposition of the emitted light, the optical axes may be aligned perpendicular to an arrangement plane of the optical elements. In this case, every second axial spacing between a first and a second optical axis can have the same magnitude and/or the same alignment along a first arrangement direction. First and second axial spacings can alternate regularly along the first arrangement direction, with the result that by preference a periodic structure of first and second axial spacings is present along the first arrangement direction. It is conceivable that the optical axes have axial spacings with features described above and below also in a second arrangement direction, which is in the arrangement plane together with the first arrangement direction.

It may be advantageous to choose the axial spacings between stop axes of symmetry, which are approximately parallel to one another and assigned to stop portions of adjacent ocular units, to have different magnitudes and/or to align said axial spacings differently.

Further, each semiconductor laser can comprise a stack of functional layers for the laser operation, with the respective stop portion being integrated in the stack. In particular, the semiconductor lasers can be designed as so-called VCSELs (vertical-cavity surface-emitting lasers), with the propagation direction of the laser light being aligned across the stacking direction of the functional layers. In this case, the stop portion can be designed as an oxidized structure within a stack, wherein, in relation to the propagation direction of the laser light outside of the semiconductor laser, the stop portion can be arranged in front of, behind or within an active photon-generating layer of the stack. It is also conceivable to simultaneously arrange the stop portions in front and/or behind and/or within.

Provision can be made for first and second stop portions to be arranged along an imaginary stop plane in a stop arrangement, with respect to which the stop axes of symmetry are aligned perpendicularly, there preferably being the same number of first and second stop portions.

The stop portion geometries of first and second stop portions differ in respect of a cross-sectional area and/or a cross-sectional contour of their stop portion geometries of an aperture. Purely by way of example, the stop portion geometries of at least two directly adjacent stop portions may differ from one another in respect of the cross-sectional area and/or the cross-sectional contour of an aperture. For example, the cross-sectional area contains the surface area of the stop portion along a plane of main extent of the stop portion. In particular, the cross-sectional area may comprise the area of the aperture, by means of which the laser light is bounded during the passage through the stop portion. By way of example, the aperture can be understood to be a clear width. The cross-sectional contour is the edge delimiting the aperture. For example, at least some of the cross-sectional contour can be round or polygonal. Further, the cross-sectional contour may vary from stop portion to stop portion but the surface area of the cross-sectional area can nevertheless be the same size. By way of example, a dimension such as the width of the stop portions may be varied from stop portion to stop portion along an arrangement direction.

By preference, the stop portions are arranged in an imaginary stop plane, with respect to which the stop axes of symmetry are aligned perpendicularly, with second stop portions having identical designs. In this case, the first and second stop portions can be arranged alternately along a first and/or a second arrangement direction. The stop portions of a laser device may be arranged in a joint stop plane. The stop plane is aligned across the stacking direction of the stack of functional layers underlying the semiconductor laser. By preference, the configuration of the stop portion repeats in respect of the cross-sectional area and/or the cross-sectional contour for every second stop portion, with the result that for example two embodiments of the stop portions are contained in the laser device, wherein the embodiments are able to alternate periodically along the stop plane. In an alternative, groups of first stop portions may be arranged next to groups of second stop portions.

Advantageously, the optical elements are designed as refractive lenses, which may each have different foci and in particular focal lengths. In this case, some of the foci can be arranged in a common focal plane while the remaining foci are not located in the focal plane. This can achieve a superposition of the laser light emitted by a semiconductor laser in each case, wherein inhomogeneities in the light intensity of the laser light from the respective semiconductor lasers can be compensated for in particular.

The same number of foci can be located in and outside of the focal plane, with by preference every second optical element being located in the same focal plane. A periodically alternating alignment of the foci can be advantageous if the foci of every second optical element are located in the same focal plane. This achieves a systematic compensation of the inhomogeneities in the light intensity of the laser light from the semiconductor lasers. The remaining foci can either be located in at least one further common focal plane or be distributed as desired in front of and/or behind the focal plane in the propagation direction.

In the case of an efficient embodiment in respect of the imaging sharpness of the stop portion on the illuminated surface, the stop plane coincides with the focal plane at least in portions. Further, the active layer or another portion of the semiconductor laser can be located in the focal plane. In this case, the foci are located in the stop plane and preferably directly on the stop portion.

In a special development, a laser light cone emerging from an ocular unit has local intensity extrema in particular, which are at least partly compensated by corresponding intensity extrema of a laser light cone of at least one adjacent ocular unit. For example, local intensity maxima and minima may occur within the laser light cone. The intensity extrema may be caused by laser light modes that set in as a result of the semiconductor laser dimensions. If the semiconductor laser dimensions of the semiconductor lasers in the same laser device are identical, identical or similarly manifested intensity extrema preferably occur in different laser light cones from the same laser device. Therefore, the intensity maxima and minima of different laser light cones can be mixed with one another for mutual compensation. By way of example, the semiconductor laser dimensions can be approximately 15 to 30 micrometers.

In an advantageous embodiment, provision can be made for the intensity extrema of the different laser light cones to be displaced from one another along a lateral axis aligned across an optical axis or optics axis of the optical element, with the result that at least one intensity maximum of a first laser light cone and at least one intensity minimum of an adjacent laser light cone is superimposed. If the distribution of the intensity maxima and minima of different laser light cones is identical, then a superposition of the intensity maxima and the intensity minima can be achieved by a lateral displacement of one of the laser light cones by a width of an intensity maximum or minimum. This brings about a homogenization of the light intensity.

It is understood that the features specified above and the features yet to be explained below can be used not only in the respectively specified combination but also in other combinations.

In particular, the features regarding the stop portions and the optical elements of the various embodiments can be combined with one another.

The described measures for varying the emitted laser light can be approximately no more than 10% and preferably 5%.

The figures of the drawing show laser devices 10 for creating an overall radiation resulting from a plurality of individual radiations, having an array-like semiconductor laser arrangement 12 comprising a plurality of semiconductor lasers 13.

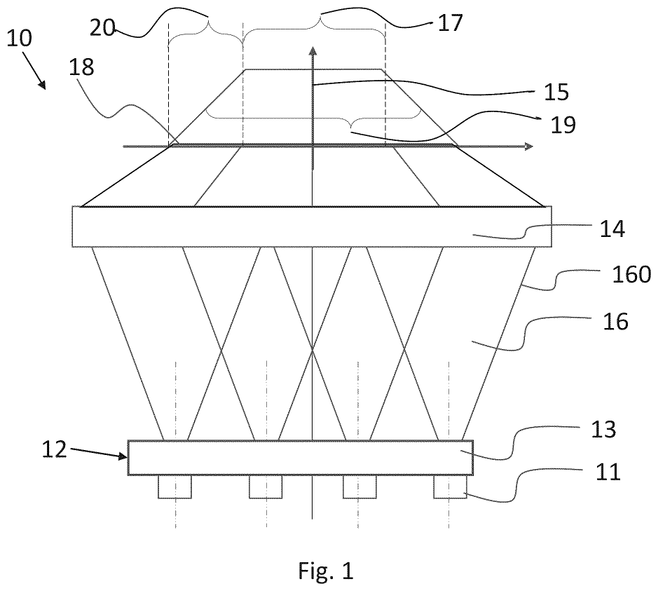

FIG. 1 depicts a laser device 10 known from the prior art. According to FIG. 1, as known per se, a semiconductor laser arrangement 12 comprising at least one VCSEL array is used in combination with a separate optical diffuser 14 for the purposes of illuminating a scene to be recorded by a camera. For example, such diffusers can be used in portable equipment with a photography function in order to obtain a uniform illumination of the scene located in the far field. In particular, the semiconductor laser arrangement 12 contains semiconductor lasers 13 which are designed as so-called VCSELs (vertical-cavity surface-emitting lasers). Stop portions 11 are assigned to the individual semiconductor lasers 13.

In the case of a laser device equipped with a diffuser, the respective stop portion 11 has a function of a current aperture and laterally delimits a current guided by electrical contacts to the active layer.

The optical diffusers 14, which for example have the property of what is known as milky glass, scatter the laser light 16 emitted by the VCSEL array 12. This creates an indifferent light emission starting from the diffuser 14, which ensures that an area 18 positioned within the scene is illuminated.

If a central axis of symmetry of the diffuser 14 aligned orthogonal to the plane of main extent of the diffuser 14 is considered, then the light intensity 15 reduces radially outwardly along the illuminated area 18 starting from the axis of symmetry. The light intensity 15 in a central zone 17 can be sufficiently high for photographic recordings with, in particular, a smartphone camera or any other camera device.

The laser light 16 emerges from the semiconductor laser 13 as a laser light cone 160. The laser light cones 160 superimpose at the diffuser 14, with the light intensity 15 being higher the more laser light cones 160 are superimposed. The multiple superposition creates an illumination of the area 18 with a beam angle of 60°. The central zone 17 can preferably be comprised by the half-value width in the illuminated area 18 that corresponds to the beam angle 19.

In contrast to the central zone 17, the light intensity 15 is lower in the region of edge regions 20 of the illuminated area 18. The light intensity 15 successively reduces radially outwardly. According to this, the light intensity 15 in the edge region 20 of the illuminated area 18 can be below the light intensity 15 required for a majority of the camera applications. Starting from the central zone 17, the light intensity 15 decreases continuously with a slope of approximately 20°.

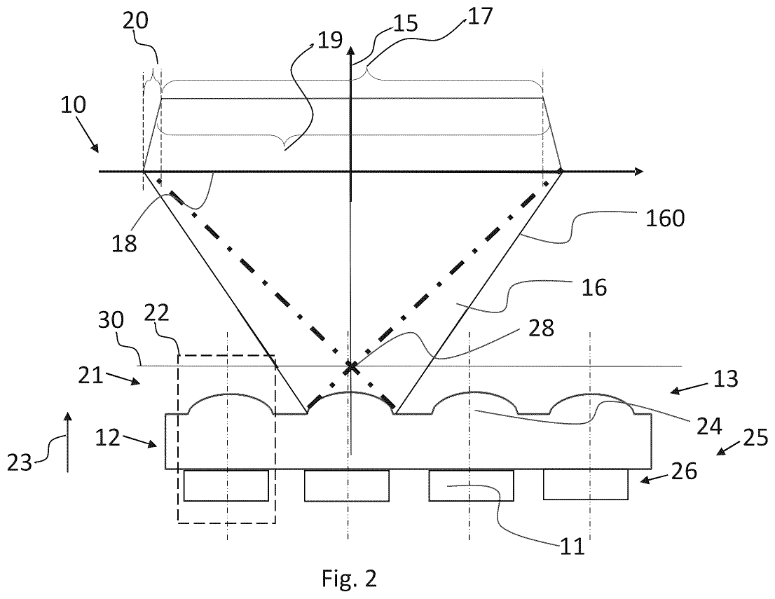

FIG. 2 shows a laser device comprising at least one ocular arrangement 21 from a plurality of ocular units 22. The ocular unit 22 in each case comprises a stop portion 11 of a semiconductor laser 13 and an optical element 24 assigned to the semiconductor laser 13.

The ocular unit 22 is preferably a unit, marked by a dashed box in FIG. 2, made of the stop portion 11 and the optical element 24 of a semiconductor laser 13. The laser light 16 emerges from the ocular unit 22 as a laser light cone 160. The stop portion 11 is imaged on the area 18 by the ocular unit 22.

The respective stop portion 11 can be integrated in the semiconductor laser 13. The semiconductor laser 13 is constructed from a stack of functional layers for the laser operation of the semiconductor laser 13, which are stacked one on top of another in a stacking direction 23. The stacks of the semiconductor lasers 13 preferably embodied as so-called VCSELs (vertical-cavity surface-emitting lasers) are stacked in the propagation direction of the laser light 16.

The respective stop portion 11 is integrated as a so-called oxide stop, for example, into the stack and acts as a current aperture and/or as a light aperture. Further, the stop portion 11 in the type of a stop has an aperture. The stop portion 11 is preferably arranged as an oxidized structure within the stack in front of, behind or within a photon-generating active layer of the stack.

The optical element 24 is designed as a refractive lens integrated in the stack, said refractive lens preferably being formed on an outer side of the stack. In an alternative or in addition, the lens may contain a photonic metamaterial.

In comparison with a laser device 10 having a diffuser 14, the aperture is imaged more sharply on the area to be illuminated as a result of the ocular unit 22. That is to say, the edge region 20 in the case of a laser device 10 having an ocular unit 22 covers a smaller portion of the area than in the case of a laser device 10 having a diffuser 14. This leads to the slope with which the light intensity 15 decreases being higher if the light intensity 15 of a central zone 17 of an area 18 illuminated by a laser device 10 having an ocular unit 22 is of the same magnitude as in the case of a laser device 10 having a diffuser 14.

The light intensity curves of the light intensity 15 depicted in the figures are purely schematic. By preference, the light intensity curve is characterized by a so-called top-hat radiation and is formed with a beam angle 19 of approximately 60° in particular. In the central zone 17, the light intensity curve has an at least approximately stationary light intensity 15 along the area 18. The edge region 20 is the portion of the light intensity curve which surrounds the central zone 17 and which falls to a global intensity minimum.

If the laser light cones 16 of a plurality of semiconductor lasers 13 are superimposed on one another, then the light intensity 15 is increased in the central zone 17. This further increases the slope of the edge region 20, and the edge region 20 appears even sharper. The homogeneity of the light intensity 15 along the central zone 17 can be increased by the superposition of the laser light cones 160 from different ocular units 22. To this end, the images of the stop portions 11 are projected onto one another preferably exactly.

By preference, a plurality of ocular units 22 are arranged next to one another across the stacking direction 23 of the functional layers in the ocular arrangement 21. The optical elements 24 of the ocular units 22 are preferably formed in one piece in a semiconductor laser arrangement 12 comprising the semiconductor lasers 13. The semiconductor lasers 13 can be formed in a portion of a first wafer. The optical elements 24 can be formed in the same portion of the first wafer. The same portion of the first wafer may comprise the stack forming the semiconductor laser 13. In an alternative, the optical elements 24 can be integrated in a further portion of a second wafer which is attached to the portion of the first wafer comprising the semiconductor lasers 13.

The stop portions 11 are arranged next to one another in an imaginary stop plane such that the respective cross-sectional contours of the apertures are arranged in a stop plane aligned perpendicularly to the stacking direction 23. In this case, the stop portions 11 are arranged in the same layer or arranged in different layers which are arranged at the same level in the stacking direction 23. In an alternative or in addition, the stop portions 11 may also be arranged in layers arranged on different levels. The stop portions 11 are arranged in a stop arrangement 26 extending along the stop plane.

The optical elements 24 designed as refractive lenses may preferably have different foci 28 from one another. Foci 28 can be so-called focal points which are characterized by a focal length of the lens in particular. In FIG. 2, the beam path through the focus 28 is depicted schematically by a dash-dotted line. In particular, each lens has a focus. By preference, first foci 28 can be arranged in a first focal plane 30 and second foci 28 can be arranged not in the first focal plane 30. To this end, the first and second foci 28 along the first focal plane can be located on and next to the first focal plane, respectively, in periodically alternating fashion. In particular, the focus 28 of every second optical element 24 can be located in the same focal plane. In relation to the propagation direction of the laser light 16, the foci 28 not located in the focal plane can be located in front of and/or behind the focal plane, in particular in alternating fashion. The second foci 28 can be located in at least one second focal plane which is positioned parallel to the first focal plane 30.

The optical elements 24 arranged in array-like fashion are preferably lenses which form a lens arrangement 25. The lens arrangement 25 is positioned in an arrangement plane aligned perpendicularly to the optical axis of the lenses.

In a further embodiment, the stop plane and the focal plane 30 can coincide at least in portions. In this case, the foci 28 are located in the stop plane and preferably directly on the stop portion 11 or in the aperture. The focal plane 28 can also be located in the arrangement plane of the semiconductor laser arrangement 12.

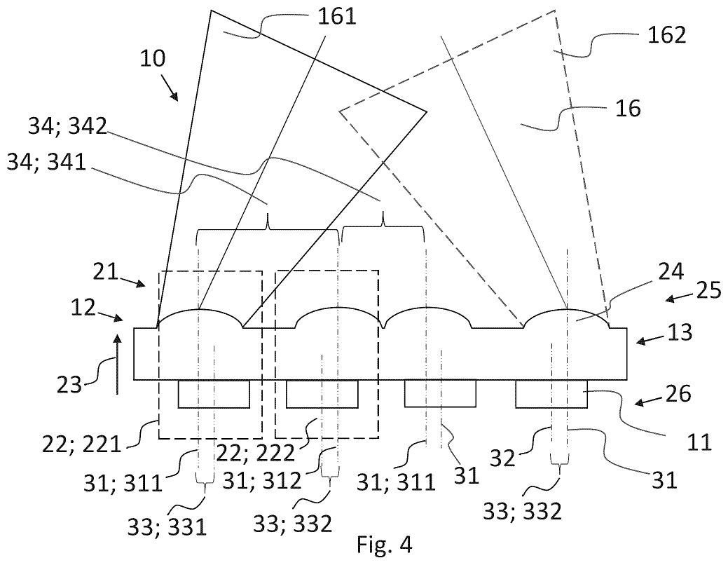

The various embodiments of the foci 28 can be combined with the embodiments in FIGS. 4 and/or 5.

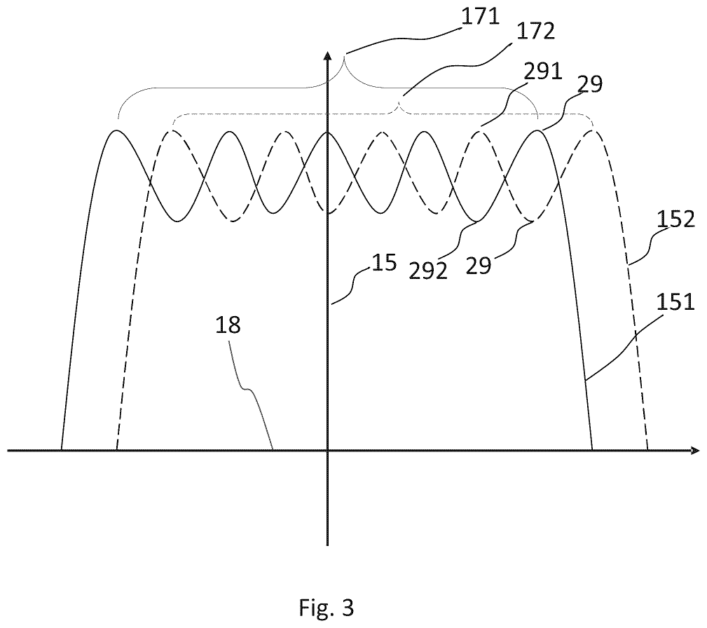

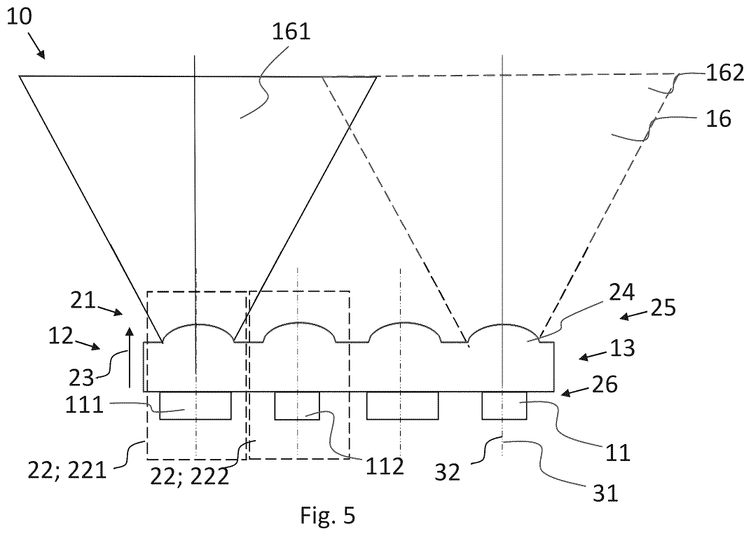

FIG. 3 depicts an intensity diagram of the laser light 16 of a first laser light cone 161 and a second laser light cone 162 illuminating the area 18, with an intensity curve 151 of the first laser light cone 161 being plotted using a solid line and an intensity curve 152 of the second laser light cone 162 being plotted using a dashed line. The first and the second laser light cone 161, 162 are depicted in the exemplary embodiments of FIGS. 4 and 5.

The light intensity 15 is inhomogeneous in the central zone 171, 172 of the first and the second intensity curve. The laser light 16 emerging from the respective ocular unit 22 has local intensity extrema 29, which, as intensity maxima and minima, are distributed preferably approximately periodically over the first and second central zone 171, 172.

An intensity maximum 291 of the first intensity curve 151 can be at least partly compensated by an intensity minimum 292 of the second intensity curve 152. This achieves a systematic compensation of the inhomogeneities in the light intensity 15 of the laser light 16 from the respective semiconductor lasers 13.

The intensity extrema 29 of the first and the second laser light cone 161, 162 can be superimposed on one another if the first and the second intensity curve 151, 152 are displaced along the area 18 to be illuminated. To this end, the laser light cones of the laser light 16 underlying the first and the second intensity curve 151, 152 can be displaced from one another, at least approximately along a lateral axis aligned across an optical axis 31 of the optical element 24. The lateral axis is aligned approximately parallel to the area 18 to be illuminated. The optical element 24 approximately corresponds to an optical axis 31 of the optical element 24, with the result that at least one intensity maximum 291 of a first laser light cone 161 and at least one intensity minimum 192 of a second laser light cone 162 are superimposed. If the distribution of the intensity maxima and minima 291, 292 of different laser light cones 161, 162 is identical, then a superposition of the intensity maxima 291 and the intensity minima 192 can be achieved by a simple displacement of the laser light cones 161, 162 with respect to one another by an integer multiple of the width of an intensity maximum or minimum. In particular, the laser light cones can each be displaced by the absolute value of an integer quarter of the distance between the two outermost intensity maxima of the respective intensity curve 151, 152, formed along the illuminated area 18, wherein the integer quarter is divided by the number of intensity maxima reduced by the number one.

For example, the laser devices 10 from FIGS. 4 and 5 can be provided for displacing the intensity minima 29 of the first and the second intensity curve 151, 152 from one another.

FIG. 4 depicts a laser device 10 whose optical elements 24 are spaced differently from one another.

In order to achieve a superposition of the intensity minima 29 of the first and the second intensity curve 151, 152, the ocular units 22 of an ocular arrangement 21 may have different constructions. By way of example, the relative positions between the stop portion 11 and the optical element 24 of a first ocular unit 221 may differ from the at least one second ocular unit 222.

The relative position between the stop portion 11 and the optical element 24 is essentially distinguished by an axial spacing 33 between the optical axis 31 and a stop axis of symmetry 32. The stop axis of symmetry 32 is aligned perpendicularly to the stop plane and preferably represents a rotational axis of symmetry. The optical axis 31 can be understood to be an optical axis of the beam path of the laser light 16 propagating through the optical element 24.

The optical axes 31 and the stop axes of symmetry 32 are aligned parallel to one another. The axial spacing is the distance between two axes. The axial spacing is aligned perpendicular to the axes.

According to the exemplary embodiment in FIG. 4, the axial spacings between the respective stop axes of symmetry 32 of adjacent stop portions 11 of the stop portion arrangement are identical along an arrangement direction of the stop plane. The axial spacings 34 between the optical axes 31 of adjacent optical elements 24 are not identical. This leads to the stop axis of symmetry 32 being displaced with respect to the optical axis 31 at least in some of the ocular units 22. By way of example, the stop axis of symmetry 32 can approximately be located on the optical axis 31 in another part of the ocular units 22.

For example, the axial spacings 341, 342 between at least one second optical axis 312 and at least two directly adjacent first optical axes 311 may have different magnitudes.

In the case of a periodically repeating structure of the axial spacings 341, 342, every second axial spacing 342 between a first and a second optical axis 311, 312 can have the same magnitude along the arrangement direction. The second axial spacings 342 between the optical axes 311, 312 are different from first axial spacings 341 in respect of their magnitude and/or alignment. Along an arrangement direction, first and second axial spacings 341, 342 can alternate regularly in respect of magnitude and/or alignment, with the result that by preference there is a periodic structure of first and second axial spacings 341, 342 along the arrangement direction of the optical axes 311, 312.

According to a further exemplary embodiment, a number of first axial spacings between optical axes 31 can equal a number of second axial spacings between partially different optical axes 31, wherein the first and second axial spacings need not be periodically repeating. For a superposition of the laser light cones in the far field, it is sufficient if at least one group of first axial spacings and a group of second axial spacings with approximately the same number of axial spacings are present in the laser device.

Moreover, along an arrangement direction aligned perpendicularly to the optical axes 31, the optical axes 31 of the respective ocular units 22 can be displaced to different sides of the stop axis of symmetry 32 assigned to the respective ocular unit 22. As a result, the axial spacings between the ocular unit 22 and the associated stop axis of symmetry 32 are different not only in respect of the magnitude of the respective axial spacing 31 but also in respect of the alignment of the axial spacings in relation to an arrangement direction perpendicular to the optical axes 31.

In particular, the magnitude and/or the alignment of the axial spacings 31 repeat along the arrangement direction. By preference, the magnitude and/or the alignment repeat at every second axial spacing 332 along the arrangement direction.

As a result of the displacement of the optical axis 31 vis-à-vis the stop axes of symmetry 32, it is preferably possible to achieve a deflection of the light propagation direction from a light propagation direction aligned perpendicular to the arrangement plane. The deflection of the light propagation direction from the perpendicular approximately brings about a displacement of the light intensity curves as per FIG. 3.

FIG. 5 shows a further embodiment leading to a displacement of the light intensity curves. The embodiment in FIG. 5 can be combined with the embodiment in FIG. 4.

The laser device 10 comprises an array-like arrangement of the optical elements 24, in which the optical axes 31 have a preferably identical axial spacing from directly adjacent optical axes 31. By preference, the stop axis of symmetry 32 of an ocular unit 22 is located in each case on an optical axis 31 assigned to the ocular unit 22. In particular, the stop axes of symmetry 32 have an identical axial distance from directly adjacent stop axes of symmetry 32.

A stop portion geometry of the respective stop portion 11 of a first ocular unit 221 differs from the stop portion geometry of the stop portion 11 of at least one second ocular unit 222.

The stop portion geometry of at least two directly adjacent stop portions 11 may differ in respect of a cross-sectional area and/or the cross-sectional contour of the aperture. For example, the cross-sectional area contains the surface area of the stop portion 11 or the aperture along a plane of main extent of the respective stop portion 11 or along the stop plane. In particular, the cross-sectional area may comprise the aperture, by means of which the laser light 16 is bounded during the passage through the stop portion 11.

The cross-sectional contour of the aperture is specified by the edge thereof. For example, the cross-sectional contour can be round at least in part, can have straight portions or can have corners. Further, the cross-sectional contour may vary from stop portion 11 to stop portion 11 but the surface area of the cross-sectional area can nevertheless be equal.

By way of example, a dimension such as the width of the stop portions 11 may be varied from a first stop portion 111 to a second stop portion 112 along an arrangement direction. In this case, the first stop portion 111 can be larger than the second stop portion 112, wherein the width of the second stop portion 112 can be smaller than the width of the first stop portion 111 by an integer half, wherein the integer half is divided by the number of intensity maxima.

In the stop arrangement formed by the stop portions 11, every second stop portion 112 along an arrangement direction lying in the stop plane can have an identical embodiment.

The configuration of the stop portion 111, 112 repeats in respect of the cross-sectional area and/or the cross-sectional contour in every second stop portion 112, with the result that two different stop portions 111, 112 are contained in the stop arrangement 26, wherein the different stop portions 111, 112 alternate periodically along at least one arrangement direction of the stop plane. By preference, the different stop portions 111, 112 can be arranged along a first and a second arrangement direction.

In a further embodiment, a first group can have the same number of first stop portions as a second group has second stop portions. The displacement of the laser light cones created thereby creates a superposition in the far field.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

10 Laser device
11 Stop portion
111 First stop portion
112 Second stop portion
12 Semiconductor laser arrangement
13 Semiconductor laser
14 Diffuser
15 Light intensity
151 First intensity curve
152 Second intensity curve
16 Laser light
160 Laser light cone
161 First laser light cone
162 Second laser light cone
17 Zone
171 Central zone
172 Central zone
18 Illuminated area
19 Beam angle
20 Edge region
21 Ocular arrangement
22 Ocular unit
221 First ocular unit
222 Second ocular unit
23 Stacking direction
24 Optical element
25 Lens arrangement
26 Stop arrangement
28 Focus
29 Intensity extrema
291 Intensity maximum
292 Intensity minimum
30 Focal plane
31 Optical axis
311 First optical axis
312 Second optical axis
32 Stop axis of symmetry
33 Axial spacing
331 First axial spacing
332 Second axial spacing
34 Axial spacing
341 First axial spacing
342 Second axial spacing

1. A laser device comprising:
a semiconductor laser arrangement comprising a plurality of semiconductor lasers, and
an ocular arrangement comprising a plurality of ocular units, each ocular unit comprising a stop portion of a respective semiconductor laser and an optical element, wherein each respective semiconductor laser corresponds to a respective ocular unit such that laser light emitted by the respective semiconductor laser and delimited by the stop portion propagates through the optical element of the respective ocular unit, wherein a relative position of the stop portion with respect to the optical element of a first ocular unit differs from a relative position of the stop portion with respect to the optical element of at least a second ocular unit, and/or wherein a stop portion geometry of the stop portion of the first ocular unit differs from the stop portion geometry of the stop portion of the second ocular unit.

2. The laser device as claimed in claim 1, wherein the stop portion has a stop axis of symmetry, and the optical element has an optical axis, and wherein the stop axis of symmetry and the optical axis of an ocular unit coincide with one another or are approximately parallel to one another at an axial spacing relative to one another.

3. The laser device as claimed in claim 2, wherein the optical axes of the optical elements from different ocular units are aligned approximately parallel to one another, and wherein spacings of a first optical axis with respect to two directly adjacent second optical axes have different magnitudes and/or different alignments.

4. The laser device as claimed in claim 2, wherein the optical axes of the optical elements are aligned perpendicular to an arrangement plane of the optical elements, and wherein a first spacing between a first optical axis and a second optical axis adjacent to the first optical axis differs from a second spacing between the first optical axis and a third optical axis adjacent the first optical axis.

5. The laser device as claimed in claim 4, wherein the first spacing and the second spacing have different magnitudes and/or different alignments along at least one arrangement direction.

6. The laser device as claimed in claim 4, wherein there are a plurality of first spacings and a plurality of second spacings, and wherein a number of the first spacings is equal to a number of the second spacings.

7. The laser device as claimed in claim 2, wherein the optical elements are arranged in an array arrangement formed as a one-piece lens arrangement, wherein spacings between a first optical axis and directly adjacent second optical axes repeat periodically along the array arrangement.

8. The laser device as claimed in claim 7, wherein spacings between the first optical axis and the second optical axes have a same magnitude and/or a same alignment along at least one arrangement direction.

9. The laser device as claimed in claim 2, wherein spacings between stop axes of symmetry of stop portions of adjacent ocular units have different magnitudes and/or alignments.

10. The laser device as claimed in claim 1, wherein each semiconductor laser comprises a stack of functional layers for laser operation, and wherein the respective stop portion is integrated in the stack.

11. The laser device as claimed in claim 2, wherein first stop portions and second stop portions are arranged along an imaginary stop plane in a stop arrangement, wherein the stop axes of symmetry are aligned perpendicular to the imaginary stop plane, and wherein a number of first stop portions is equal to a number of second stop portions.

12. The laser device as claimed in claim 11, wherein the first stop portions and the second stop portions differ in terms of a cross-sectional area and/or a cross-sectional contour of stop portion geometries of an aperture.

13. The laser device as claimed in claim 1, wherein the optical elements are configured as refractive lenses with different focal lengths.

14. The laser device as claimed in claim 13, wherein a number of foci located in a focal plane is equal to a number of foci located outside the focal plane, and wherein every other optical element is located in the focal plane.

15. The laser device as claimed in claim 14, wherein the stop portions are arranged along an imaginary stop plane in a stop arrangement, and wherein the stop plane coincides with the focal plane at least in portions.

16. The laser device as claimed in claim 1, wherein the semiconductor lasers are vertical-cavity surface emitters.

17. The laser device as claimed in claim 1, wherein a first laser light cone emerging from an ocular unit has local intensity extrema, which are at least partly compensable by corresponding local intensity extrema of a second laser light cone of at least one other ocular unit.

18. The laser device as claimed in claim 17, wherein the local intensity extrema of the different laser light cones are displaced from one another along a lateral axis aligned across an optical axis of the optical element, so that at least one intensity maximum of the first laser light cone and at least one intensity minimum of the second laser light cone are superimposed.
